(19) United States
(12) Patent Application Publication
(10) Pub. No.: US 2017/0076982 A1
(43) Pub. Date: Mar. 16, 2017

(54) DEVICE MANUFACTURING METHOD

(71) Applicant: Kabushiki Kaisha Toshiba, Tokyo (JP)

(72) Inventors: Seiya Sakakura, Kanazawa Ishikawa (JP); Masamune Takano, Kanazawa Ishikawa (JP); Yusaku Asano, Yokohama Kanagawa (JP); Keiichiro Matsuo, Yokohama Kanagawa (JP)

(21) Appl. No.: 15/050,683

(22) Filed: Feb. 23, 2016

(30) Foreign Application Priority Data
Sep. 11, 2015 (JP) 2015-179157

(51) Int. Cl. H01L 21/78; H01L 21/3065; H01L 21/683; H01L 21/56; H01L 23/544

(52) U.S. Cl. CPC H01L 21/78; H01L 21/568; H01L 23/544; H01L 21/6836; H01L 21/3065; H01L 2223/54453

(57) ABSTRACT

Provided is a device manufacturing method according to an embodiment including forming a film on a second plane side of a substrate having a first plane and the second plane, forming grooves on the substrate from the first plane side so that the film remains, and performing an ultrasonic process on the substrate in a liquid to remove the film of the second plane side at positions where the grooves are formed.

### CROSS-REFERENCE TO RELATED APPLICATION

This application is based upon and claims the benefit of priority from Japanese Patent Application No. 2015-179157, filed on Sep. 11, 2015, the entire contents of which are incorporated herein by reference.

### FIELD

Embodiments described herein relate generally to a device manufacturing method.

### BACKGROUND

A plurality of semiconductor devices formed on a semiconductor substrate such as a wafer are divided into a plurality of semiconductor chips by dicing along dicing regions provided in the semiconductor substrate. In a case where a metal film which becomes electrodes of semiconductor devices or a resin film such as a die bonding film is formed on one surface of the semiconductor substrate, a metal film or a resin film of a dicing region in the dicing needs to be removed.

As a method of removing the metal film or the resin film, for example, there is a method of removing the semiconductor substrate and the metal film or the resin film simultaneously by blade dicing. In this case, shape abnormality such as a projection (burr) easily occurs in the metal film or the resin film. If the shape abnormality occurs in the metal film or the resin film, the semiconductor chip becomes defective in visual inspection, or a defect of connection between a chip bed and the semiconductor chip occurs, so that there is a problem in that the product yield is decreased.

### BRIEF DESCRIPTION OF THE DRAWINGS

FIGS. 1A to 1F are schematic process cross sectional diagrams illustrating a device manufacturing method according to a first embodiment.

FIGS. 2A to 2F are schematic process cross sectional diagrams illustrating a device manufacturing method according to a second embodiment.

FIGS. 3A to 3F are schematic process cross sectional diagrams illustrating a device manufacturing method according to a third embodiment.

FIGS. 4A to 4F are schematic process cross sectional diagrams illustrating a device manufacturing method according to a fourth embodiment.

FIGS. 5A to 5E are schematic process cross sectional diagrams illustrating a device manufacturing method according to a fifth embodiment.

FIGS. 6A and 6B are optical microscope pictures after dicing according to an example.

FIGS. 7A and 7B are SEM pictures after dicing according to the example.

### DETAILED DESCRIPTION

A device manufacturing method according to an embodiment includes forming a film on a second plane side of a substrate having a first plane and the second plane, forming grooves on the substrate from the first plane side so that the film remains, and performing an ultrasonic process on the substrate in a liquid to remove the film at positions where the grooves are formed.

Hereinafter, embodiments of the present invention will be described with reference to the drawings. In addition, in the description hereinafter, the same or similar components are denoted by the same reference numerals, and redundant description of the component or the like which is described once is omitted.

### First Embodiment

A device manufacturing method according to an embodiment includes forming a film on a second plane side of a substrate having a first plane and a second plane, partially forming grooves on the substrate so that the film remains from the first plane side, and performing an ultrasonic process on the substrate in a liquid to remove the film of the second plane side at positions where the grooves are formed.

Hereinafter, a case where the to-be-manufactured device is a vertical type power metal oxide semiconductor field effect transistor (MOSFET) using silicon (Si) having metal electrodes on two sides thereof will be described as an example. In this case, the substrate becomes a semiconductor substrate. In addition, the film becomes a metal film.

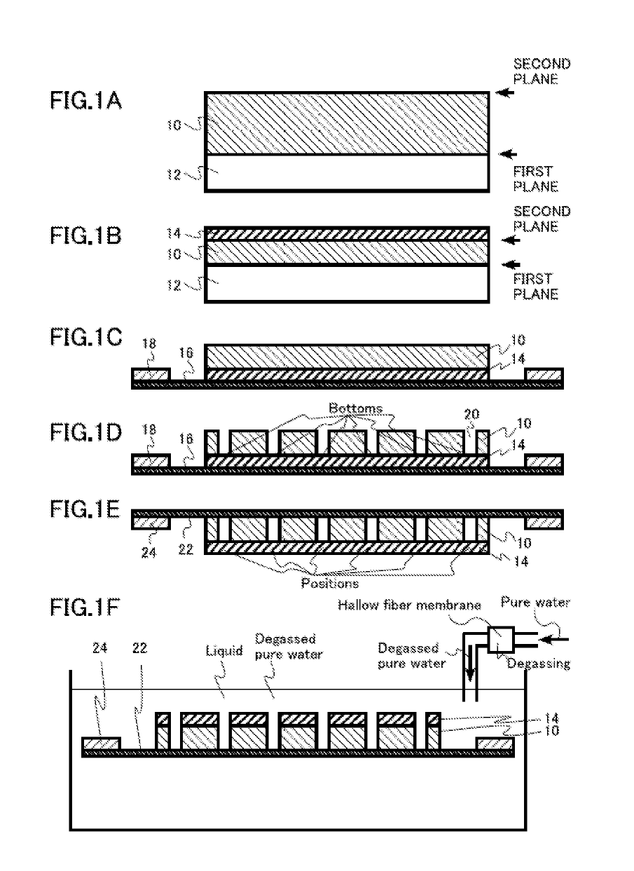

FIGS. 1A to 1F are schematic process cross sectional diagrams illustrating the device manufacturing method according to the embodiment.

A silicon substrate (substrate) 10 having a first plane (hereinafter, referred to as a front surface) and a second plane (hereinafter, referred to as a back surface) is prepared. A pattern of a base region, a source region, a gate insulating film, a gate electrode, a source electrode, and the like of a vertical type MOSFET (semiconductor device) is formed on a front surface side of the silicon substrate 10. After that, a protective film is formed on the uppermost layer of the silicon substrate 10. The protective film is, for example, a resin film such as polyimide or an inorganic insulating film such as a silicon nitride film or a silicon oxide film. Preferably, the silicon substrate 10 is exposed on the front surface of the dicing region provided in the front surface side.

Herein, the dicing region is a cutting-arranged region for dividing a plurality of semiconductor devices provided in the substrate into a plurality of semiconductor chips. The dicing region has a predetermined width. The width of the dicing region is, for example, 10 μm or more and 100 μm or less.

The dicing region is provided on the front surface side of the silicon substrate 10. The pattern of the semiconductor devices are not formed in the dicing region. The dicing region is, for example, provided on the front surface side of the silicon substrate 10 in a lattice shape so as to partition the semiconductor devices.

Next, a support substrate (support body) 12 is bonded to the front surface side of the silicon substrate 10 (FIG. 1A) The support substrate 12 is, for example, a quartz glass.

Next, the silicon substrate 10 is thinned by removing the back surface side of the silicon substrate 10 by grinding. After that, a metal film 14 is formed on the back surface side of the silicon substrate 10 (FIG. 1B). The metal film 14 is provided in the substantially entire surface of the back surface.

The metal film 14 is a drain electrode of the MOSFET. The metal film 14 is, for example, a stacked film of different types of metals. The metal film, 14 is, for example, a stacked film of a titanium/nickel/gold alloy from the back surface side of the silicon substrate 10.

The metal film 14 is formed by, for example, a sputtering method. The thickness of the metal film 14 is, for example, 0.5 μm or more and 3.0 μm or less.

Next, a resin sheet 16 is bonded to the back surface side of the silicon substrate 10. The resin sheet 16 is a so-called dicing sheet. The resin sheet 16 is fixed to a frame 18 of, for example, a metal. The resin sheet 16 is adhered to the front surface of the metal film 14. After that, the support substrate 12 is removed from the silicon substrate 10 (FIG. 1C).

Next, grooves 20 are partially formed on the silicon substrate 10 from the front surface side along the dicing region provided in the front surface side of the silicon substrate 10 (FIG. 1D). In forming the grooves 20, the grooves 20 are formed so that the metal film 14 of the back surface side is exposed at bottoms of the grooves.

The grooves 20 are formed by, for example, plasma etching. The plasma etching is, for example, a so-called Bosch process of repeating an isotropic etching step using fluorine (F) based radical, a protective film forming step using tetrachloride fluorine (CF₄) based radical, and an anisotropic etching step using fluorine (F) based ion.

The grooves 20 are preferably formed by performing entire surface etching with a protective film of the front surface side of the silicon substrate 10 used as a mask. According to this method, since lithography is not used, simplification and low cost of the manufacturing process can be implemented.

Next, a resin sheet (supporting film) 22 is bonded to the front surface side of the silicon substrate 10. The resin sheet 22 is a so-called dicing sheet. The resin sheet 22 is fixed to a frame 24 of, for example, a metal. The resin sheet 22 is adhered to the front surface of the protective film or the metal electrode of the front surface side. After that, the resin sheet 16 of the back surface side is removed (FIG. 1E).

Next, an ultrasonic process is performed on the silicon substrate 10 in a liquid. By the ultrasonic process, the metal film 14 of the back surface side at the positions where the grooves 20 are formed is removed (FIG. 1F). The liquid is, for example, pure water.

In terms of improving the effect of removal of the metal film 14, preferably, the liquid is degassed before the ultrasonic process. By performing the degassing of the liquid, since the propagation characteristic of an ultrasonic wave in the liquid is improved, the effect of removal of the metal film 11 is improved.

The degassing of the liquid can be performed by, for example, using a hollow fiber membrane which does not allow a liquid to permeate but allows a gas to permeate. In addition, the degassing of the liquid can also be performed by, for example, vacuum-drawing about a liquid in a vacuum container.

The ultrasonic process is performed, for example, at a frequency of 20 kHz or more and 80 kHz or less. In addition, the ultrasonic process is performed, for example, at a power of 200 W or more and 1200 W or less. In addition, the ultrasonic process is performed, for example, for a time of 1 minute or more and 20 minutes or less.

After that, a plurality of divided MOSFETs can be obtained by removing the resin sheet 22 of the front surface side of the silicon substrate 10.

Hereinafter, the function and effect of the device manufacturing method according to the embodiment will be described.

Like a vertical type MOSFET, in a case where the metal film 14 is also formed in the back surface side of the silicon substrate 10, in the dicing, the metal film 14 of the back surface side in the dicing region needs also be removed. For example, in a case where the silicon substrate 10 and the metal film 14 are simultaneously removed from the front surface side by the blade dicing, the metal film 14 at the end portions of the grooves 20 in the dicing region is rolled up in the back surface side, that is, so-called burr occurs.

If the burr of the metal film 14 occurs, for example, the semiconductor chips become defective in visual inspection, so that the semiconductor chips may not be manufactured as products. In addition, for example, in connecting the semiconductor chip and a metal bed with a bonding material such as solder, adhesiveness is deteriorated in the portion of the burr, so that connection defect may occur.

In the embodiment, after the grooves 20 are formed along the dicing region of the silicon substrate 10, the metal film 14 of portions extending over the grooves 20 is removed by an ultrasonic process. According to the embodiment, occurrence of the burr is suppressed. In addition, according to the embodiment, only the metal film 14 of the grooves 20 can be removed in a self-alignment manner.

In addition, in a case where the forming of the grooves 20 of the silicon substrate 10 is performed by blade dicing, chipping may occur in the silicon substrate 10 of the end portion of the back surface side of the grooves 20. In the embodiment, since the forming of the grooves 20 is performed by plasma etching, the chipping occurring in the silicon substrate 10 of the end portion of the back surface side of the grooves 20 can be prevented.

In addition, in a case where the forming of the grooves 20 of the silicon substrate 10 is performed by blade dicing, the dicing region needs to have a width which is equal to or larger than at least the thickness of the blade. Therefore, the width of the dicing region needs to be, for example, 50 μm or more.

In the embodiment, since the forming of the grooves 20 is performed by plasma etching, the width of the dicing region can be configured to be small. The width of the dicing region may be configured to be, for example, 10 μm or more and less than 50 μm, furthermore, 20 μm or less.

In addition, in the embodiment, the metal film is removed by physical impact according to the ultrasonic process. Therefore, for example, unlike dry etching using a chemical reaction, although the metal film is a stacked film of different types of metals, the metal film can be removed without being affected by a different in chemical property of the films. Therefore, even in the case of the stacked film of different types of metals, shape abnormality can be simply suppressed and removed.

As described above, according to the embodiment, it is possible to provide a device manufacturing method capable of suppressing shape abnormality in processing a metal film.

### Second Embodiment

A device manufacturing method according to this embodiment is different from that of the first embodiment in terms that not a metal film but a resin film is formed in the second plane side of the substrate. Hereinafter, redundant description of the same components as those of the first embodiment is omitted.

Hereinafter, a case where the to-be-manufactured device is a semiconductor memory using silicon (Si) having a resin film in a back surface side thereof will be described as an example.

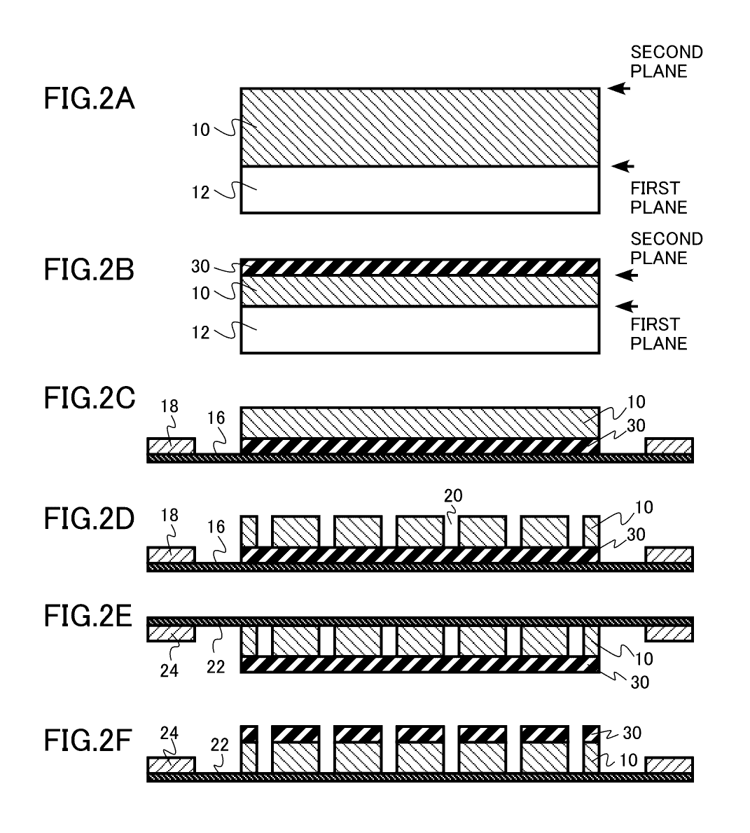

FIGS. 2A to 2F are schematic process cross sectional diagrams illustrating the device manufacturing method according to the embodiment.

A silicon substrate (substrate) 10 having a first plane (hereinafter, referred to as a front surface) and a second plane (hereinafter, referred to as a back surface) is prepared. A pattern of a memory transistor, a peripheral circuit, a power source electrode, a ground electrode, an I/O electrode, and the like of a semiconductor memory (semiconductor device) is formed on a front surface side of the silicon substrate 10. After that, a protective film is formed on the uppermost layer of the silicon substrate 10. The protective film is, for example, a resin film such as polyimide or an inorganic insulating film such as a silicon nitride film or a silicon oxide film.

Next, a support substrate 12 is bonded to the front surface side of the silicon substrate 10 (FIG. 2A). The support substrate 12 is, for example, a quartz glass.

Next, the silicon substrate 10 is thinned by removing the back surface side of the silicon substrate 10 by grinding. After that, a resin film 30 is formed on the back surface side of the silicon substrate 10 (FIG. 2B). The resin film 30 is provided in the substantially entire surface of the back surface.

The resin film 30 is, for example, a die attached film (DAF) for bonding the divided semiconductor chips to the substrate. The thickness of the resin film 30 is, for example, 10 μm or more and 200 μm or less.

Next, a resin sheet 16 is bonded to the back surface side of the silicon substrate 10. The resin sheet 16 is a so-called dicing sheet. The resin sheet 16 is fixed to a frame 18 of, for example, a metal. The resin sheet 16 is adhered to the front surface of the resin film 30. After that, the support substrate 12 is removed from the silicon substrate 10 (FIG. 2C).

Next, grooves 20 are partially formed on the silicon substrate 10 from the front surface side along the dicing region provided in the front surface side of the silicon substrate 10 (FIG. 2D). In forming the grooves 20, the grooves 20 are formed so that the resin film 30 of the back surface side is exposed.

The grooves 20 are formed by, for example, blade dicing.

Next, a resin sheet (supporting film) 22 is bonded to the front surface side of the silicon substrate 10. The resin sheet 22 is a so-called dicing sheet. The resin sheet 22 is fixed to a frame 24 of, for example, a metal. The resin sheet 22 is adhered to the front surface of the protective film or the metal electrode of the front surface side. After that, the resin sheet 16 of the back surface side is removed (FIG. 2E).

Next, an ultrasonic process is performed on the silicon substrate 10 in a liquid. By the ultrasonic process, the resin film 30 of the back surface side at the positions where the grooves 20 are formed is removed (FIG. 2F).

After that, a plurality of divided semiconductor memories can be obtained by removing the resin sheet 22 of the front surface side or the silicon substrate 10.

Hereinafter, the function and effect of the device manufacturing method according to the embodiment will be described.

For example, in a semiconductor device used for a small-sized electronic device typified by a mobile phone, such as a semiconductor memory, a ball grid array (BGA) or a multi chip package (MCP) that is a small-sized thin semiconductor package is used. In the BGA or the MCP, instead of a paste die bonding material, a film-like die bonding material such as a DAF is used.

In a case where the resin film 30 such as a DAF is formed in the back surface side of the silicon substrate 10, in the dicing, the resin film 30 of the back surface side in the dicing region needs also be removed. For example, in a case where the semiconductor substrate and the resin film 30 are simultaneously removed from the front surface side by the blade dicing, there is a problem in that the resin film 30 is peeled off from the end portions of the grooves 20 in the dicing region or the cut surface of the resin film 30 does not have a straight lined shape but have an irregular shape.

In the embodiment, after the grooves 20 are formed along the dicing region of the silicon substrate 10, the resin film 30 of portions extending over the grooves 20 is removed by an ultrasonic process. According the embodiment, peeling of the resin film 30 is suppressed. In addition, according to the embodiment, the cut surface of the resin film 30 has a straight line shape.

As described above, according to the embodiment, it is possible to provide a device manufacturing method capable of suppressing shape abnormality in processing a resin film.

### Third Embodiment

A device manufacturing method according to this embodiment is different from that of the first embodiment in terms that, in partially forming the grooves in the substrate, a portion of the substrate is allowed to remain. Hereinafter, redundant description of the same components as those of the first embodiment is omitted.

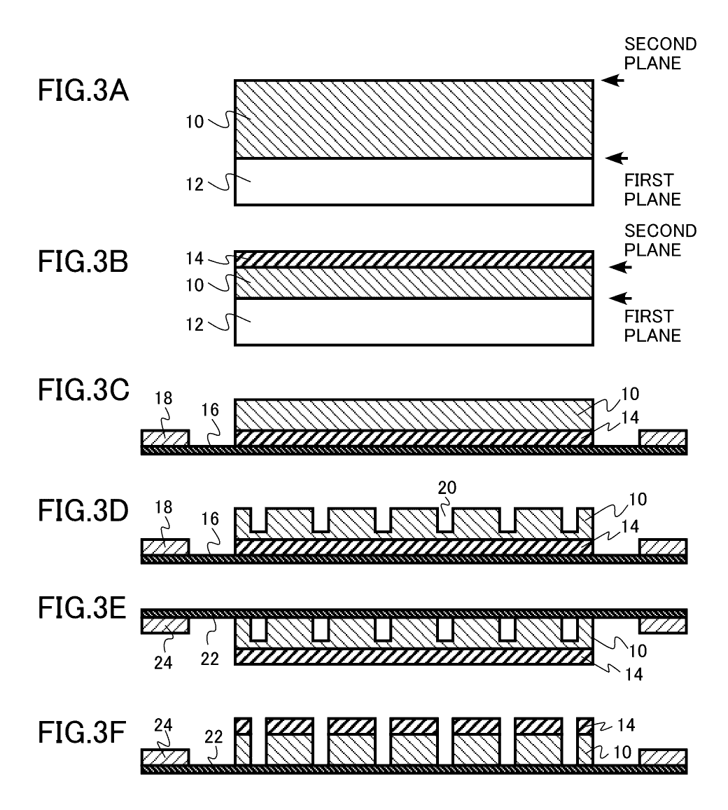

FIGS. 3A to 3F are schematic process cross sectional diagrams illustrating the device manufacturing method according to the embodiment.

A silicon substrate (substrate) 10 having a first plane (hereinafter, referred to as a front surface) and a second plane (hereinafter, referred to as a back surface) is prepared. A pattern of a base region, a source region, a gate insulating film, a gate electrode, a source electrode, and the like of a vertical type MOSFET (semiconductor device) is formed on a front surface side of the silicon substrate 10. After that, a protective film is formed on the uppermost layer of the silicon substrate 10. The protective film is, for example, a resin film such as polyimide or an inorganic insulating film such as a silicon nitride film or a silicon oxide film. Preferably, the silicon substrate 10 is exposed on the front surface of the dicing region provided in the front surface side.

Next, a support substrate (support body) 12 is bonded to the front surface side of the silicon substrate 10 (FIG. 3A). The support substrate 12 is, for example, a quartz glass.

Next, the silicon substrate 10 is thinned by removing the back surface side of the silicon substrate 10 by grinding. After that, a metal film 14 is formed on the back surface side of the silicon substrate 10 (FIG. 3B). The metal film 14 is provided in the substantially entire surface of the back surface.

The metal film 14 is a drain electrode of the MOSFET. The metal film 14 is, for example, a stacked film of different types of metals. The metal film 14 is, for example, a stacked film of a titanium/nickel/gold alloy from the back surface side of the silicon substrate 10. The metal film 14 is formed by, for example, a sputtering method. The thickness of the metal film 14 is, for example, 0.5 μm or more and 3.0 μm or less.

Next, a resin sheet 16 is bonded to the back surface side of the silicon substrate 10. The resin sheet 16 is a so-called dicing sheet. The resin sheet 16 is fixed to a frame 18 of, for example, a metal. The resin sheet 16 is adhered to the front surface of the metal film 14. After that, the support substrate 12 is removed from the silicon substrate 10 (FIG. 3C).

Next, grooves 20 are partially formed on the silicon substrate 10 from the front surface side along the dicing region provided in the front surface side of the silicon substrate 10 (FIG. 3D). In forming the grooves 20, the grooves 20 are formed so that the silicon substrate 10 of the back surface side partially remains 20 μm or less, more preferably, 10 μm or less of the semiconductor substrate of the back surface side of the grooves 20 is allowed to remain.

The grooves 20 are formed by, for example, blade dicing. The grooves 20 may be formed by, for example, plasma etching.

Next, a resin sheet (supporting film) 22 is bonded to the front surface side of the silicon substrate 10. The resin sheet 22 is a so-called dicing sheet. The resin sheet 22 is fixed to a frame 24 of, for example, a metal. The resin sheet 22 is adhered to the front surface of the protective film or the metal electrode of the front surface side. After that, the resin sheet 16 of the back surface side is removed (FIG. 3E).

Next, an ultrasonic process is performed on the silicon substrate 10 in a liquid. By the ultrasonic process, the metal film 14 of the back surface side and the silicon substrate 10 at the positions where the grooves 20 are formed is removed (FIG. 3F).

After that, a plurality of divided semiconductor memories can be obtained, by removing the resin sheet 22 of the front surface side of the silicon substrate 10.

As described above, according to the embodiment, it is possible to provide a device manufacturing method capable of suppressing shape abnormality in processing a metal film.

### Fourth Embodiment

A device manufacturing method according to this embodiment is different from that of the second embodiment in terms that, in partially forming the grooves in the substrate, a portion of the substrate is allowed to remain. Hereinafter, redundant description of the same components as those of the second embodiment is omitted.

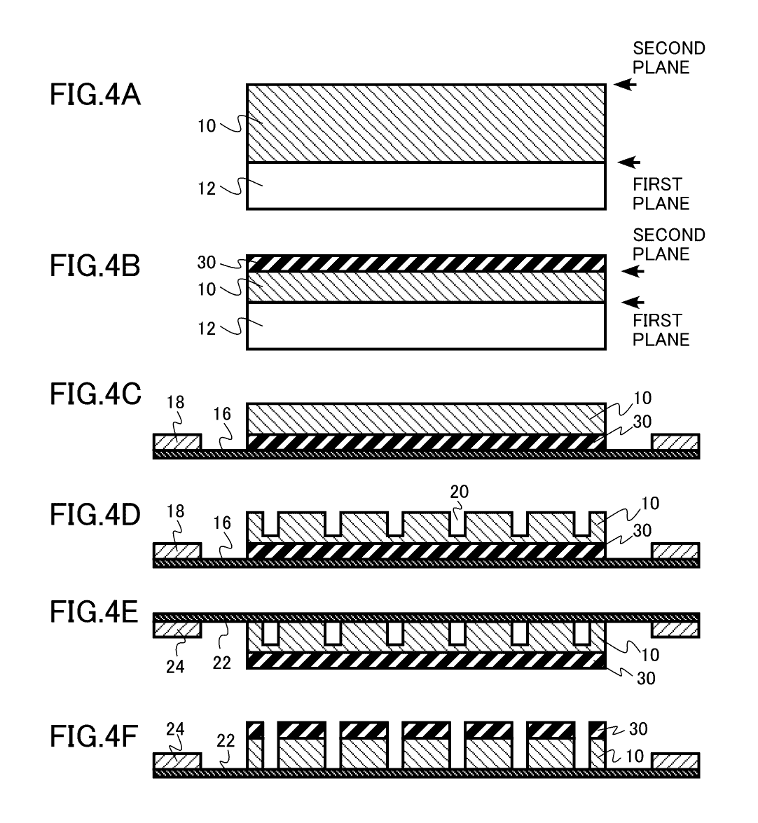

FIGS. 4A to 4F are schematic process cross sectional diagrams illustrating the device manufacturing method according to the embodiment.

A silicon substrate (substrate) 10 having a first plane (hereinafter, referred to as a front surface) and a second plane (hereinafter, referred to as a back surface) is prepared. A pattern of a memory transistor, a peripheral circuit, a power source electrode, a ground electrode, an I/O electrode, and the like of a semiconductor memory (semiconductor device) is formed on a front surface side of the silicon substrate 10. After that, a protective film is formed on the uppermost layer of the silicon substrate 10. The protective film is, for example, a resin film such as polyimide or an inorganic insulating film such as a silicon nitride film or a silicon oxide film.

Next, a support substrate 12 is bonded to the front surface side of the silicon con substrate 10 (FIG. 4A). The support substrate 12 is, for example, a quartz glass.

Next, the silicon substrate 10 is thinned by removing the back surface side of the silicon substrate 10 by grinding. After that, a resin film 30 is formed on the back surface side of the silicon substrate 10 (FIG. 4B). The resin film 30 is provided in the substantially entire surface of the back surface.

The resin film 30 is, for example, a Die Attached Film (DAF) for bonding the divided semiconductor chips to the substrate. The thickness of the resin film 30 is, for example, 10 μm or more and 200 μm or less.

Next, a resin sheet 16 is bonded to the back surface side of the silicon substrate 10. The resin sheet 16 is a so-called dicing sheet. The resin sheet 16 is fixed to a frame 18 of, for example, a metal. The resin sheet 16 is adhered to the front surface of the metal film 30. After that, the support substrate 12 is removed from the silicon substrate 10 (FIG. 4C).

Next, grooves 20 are partially formed on the silicon substrate 10 from the front surface side along the dicing region provided in the front surface side of the silicon substrate 10 (FIG. 4D). In forming the grooves 20, the grooves 20 are formed so that the silicon substrate 10 of the back surface side partially remains. 20 μm or less, more preferably, 10 μm or less of the semiconductor substrate of the back surface side of the grooves 20 is allowed to remain.

The grooves 20 are formed by, for example, blade dicing. The grooves 20 may be formed by, for example, plasma etching.

Next, a resin sheet (supporting film) 22 is bonded to the front surface side of the silicon substrate 10. The resin sheet 22 is a so-called dicing sheet. The resin sheet 22 is fixed to a frame 24 of, for example, a metal. The resin sheet 22 is adhered to the front surface of the protective film or the metal electrode of the front surface side. After that, the resin sheet 16 of the back surface side is removed (FIG. 4E).

Next, an ultrasonic process is performed on the silicon substrate 10 in a liquid. By the ultrasonic process, the resin film 30 of the back surface side and the silicon substrate 10 at the positions where the grooves 20 are formed are removed (FIG. 4F).

After that, a plurality of divided semiconductor memories can be obtained, by removing the resin sheet 22 of the front surface side of the silicon substrate 10.

As described above, according to the embodiment, it is possible to provide a device manufacturing method capable of suppressing shape abnormality in processing a resin film.

### Fifth Embodiment

A device manufacturing method according to this embodiment is different from that of the first embodiment in terms that an ultrasonic cleaning is performed in the state that the supporting film is bonded to not the first plane side but the second plane side of the substrate. Hereinafter, redundant description of the same components as those of the first embodiment is omitted.

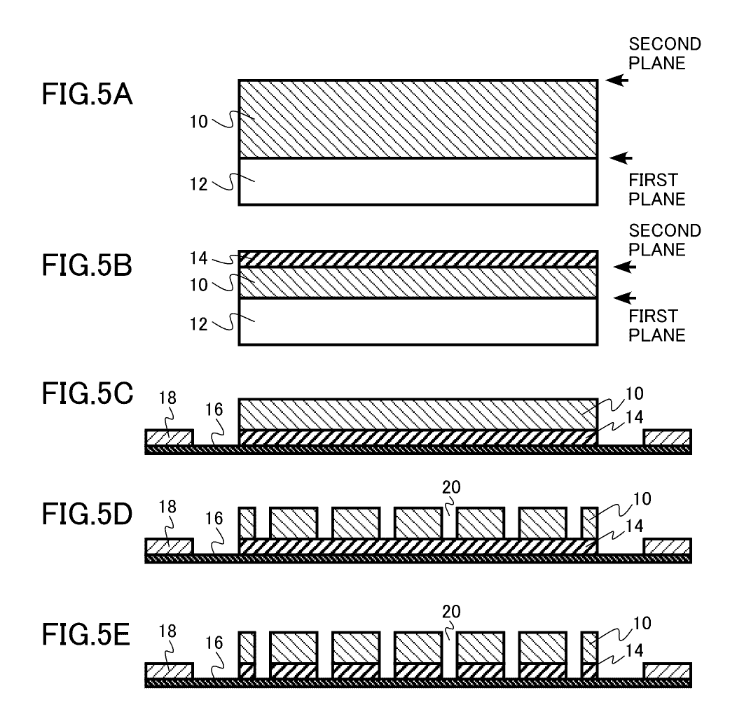

FIGS. 5A to 5E are schematic process cross sectional diagrams illustrating the device manufacturing method according to the embodiment.

A silicon substrate (substrate) 10 having a first plane (hereinafter, referred to as a front surface) and a second plane (hereinafter, referred to as a back surface) is prepared. A pattern of a base region, a source region, a gate insulating film, a gate electrode, a source electrode, and the like of a vertical type MOSFET (semiconductor device) is formed on a front surface side of the silicon substrate 10. After that, a protective film is formed on the uppermost layer of the silicon substrate 10. The protective film is, for example, a resin film such as polyimide or an inorganic insulating film such as a silicon nitride film or a silicon oxide film. Preferably, the silicon substrate 10 is exposed on the front surface of the dicing region provided in the front surface side.

Next, a support substrate (support body) 12 is bonded to the front surface side of the silicon substrate 10 (FIG. 5A). The support substrate 12 is, for example, a quartz glass.

Next, the silicon substrate 10 is thinned by removing the back surface side of the silicon substrate 10 by grinding. After that, a metal film 14 is formed on the back surface side of the silicon substrate 10 (FIG. 5B). The metal film 14 is provided in the substantially entire surface of the back surface.

The metal film 14 is a drain electrode of the MOSFET. The metal film 14 is, for example, a stacked film of different types of metals. The metal film 14 is, for example, a stacked film of a titanium/nickel/gold alloy from the back surface side of the silicon substrate 10. The metal film 14 is formed by, for example, a sputtering method. The thickness of the metal film 14 is, for example, 0.5 μm or more and 3.0 μm or less.

Next, a resin sheet (supporting film) 16 is bonded to the back surface side of the silicon substrate 10. The resin sheet 16 is a so-called dicing sheet. The resin sheet 16 is fixed to, a frame 18 of, for example, a metal. The resin sheet 16 is adhered to the front surface of the metal film 14. After that, the support substrate 12 is removed from the silicon substrate 10 (FIG. 5C).

Next, grooves 20 are partially formed on the silicon substrate 10 from the front surface side along the dicing region provided in the front surface side of the silicon substrate 10 (FIG. 5D). In forming the grooves 20, the grooves 20 are formed so that the metal film 14 of the back surface side is exposed.

The grooves 20 are formed by, for example, plasma etching.

Next, an ultrasonic process is performed on the silicon substrate 10 in a liquid. By the ultrasonic process, the metal film 14 of the back surface side at the positions where the grooves 20 are formed is removed (FIG. 5E).

After that, by removing the resin sheet 16 of the back surface side of the silicon substrate 10, a plurality of divided semiconductor memories is obtained.

As described above, according to the embodiment, it is possible to provide a device manufacturing method capable of suppressing shape abnormality in processing a metal film. In addition, the manufacturing process is simplified in comparison with the first embodiment.

### EXAMPLE

Hereinafter, examples will be described.

### Example

Dicing was performed on a silicon substrate where a plurality of semiconductor devices are formed on a front surface and a metal film is formed on a back surface. The same method as that of the first embodiment was used.

By grinding the back surface side of the silicon substrate, the thickness of the silicon substrate was set to 100 μm. Next, the metal film was formed in the back surface side of the silicon substrate by a sputtering method. The metal film was configured to be a stacked film of a titanium/nickel/gold alloy. The total thickness of the metal film was set to 2.7 μm.

Next, a dicing tape was bonded to the metal film in the back surface side of the silicon substrate. Next, grooves were formed in a dicing region by plasma etching (Bosch process) from the front surface side of the silicon substrate. The silicon substrate was etched until the metal film was exposed. The width of the groove was set to 15 μm in the horizontal direction and 30 μm in the vertical direction.

Next, the dicing tape of the back surface side of the silicon substrate was removed, and a dicing tape was bonded to the front surface side of the silicon substrate. Next, an ultrasonic process was performed on the silicon substrate in a liquid. By the ultrasonic process, the metal film of the back surface side at the positions where the grooves was formed was removed.

The ultrasonic process was performed at 38 kHz for 10 minutes in degassed pure water.

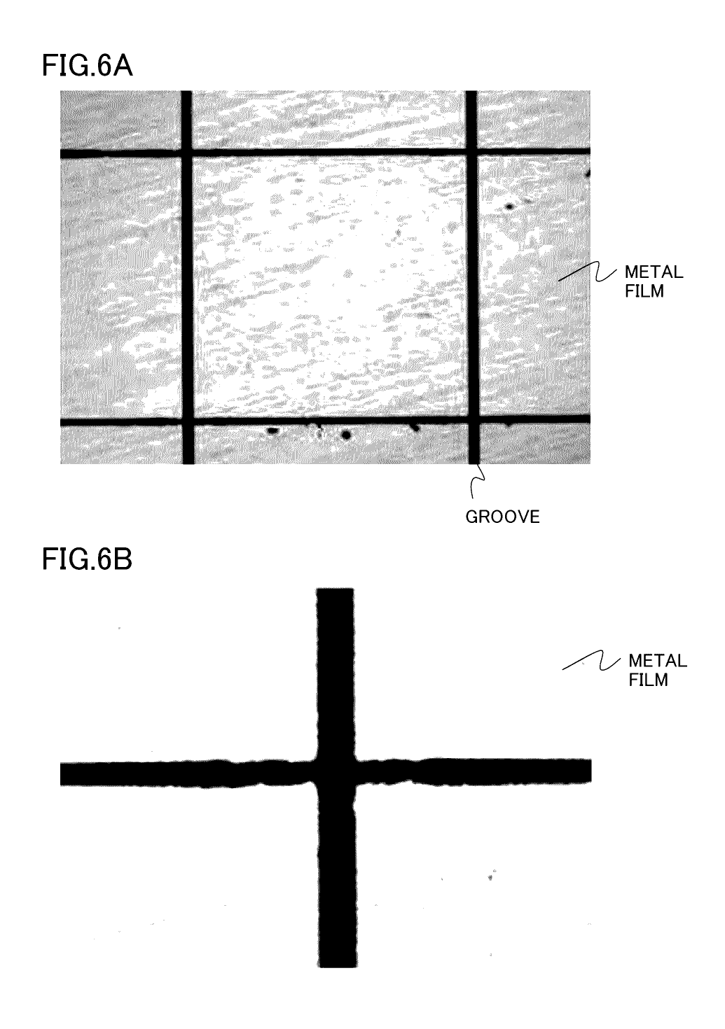

FIGS. 6A and 6B are optical microscope pictures after the dicing according to the example. FIGS. 6A and 6B are obtained by photographing from the metal film side. FIG. 6A is a low magnification picture, and FIG. 6B is a high magnification picture.

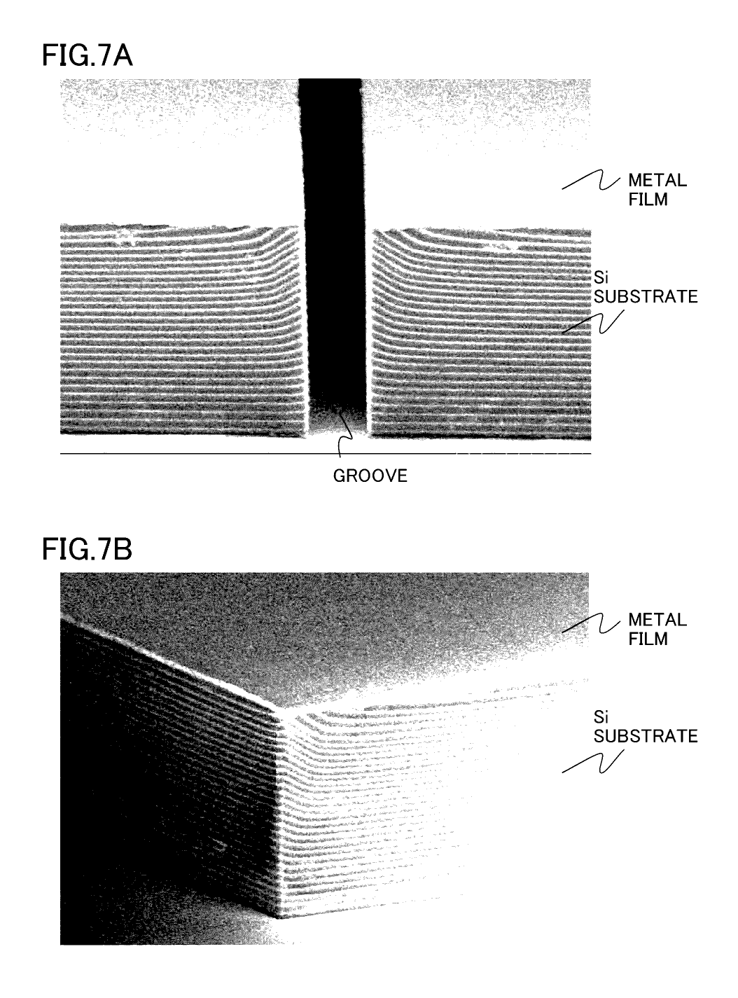

FIGS. 7A and 7B are scanning electron microprobe (SEM) pictures after dicing according to Example. FIGS. 7A and 7B illustrate states where the metal film exists in the upper side of the silicon substrate.

As clarified from FIGS. 6A and 6B, it can be understood that in any one of the cases of horizontal grooves having a width of 15 μm and vertical grooves having a width of 30 μm, the metal film is removed in a self-alignment manner with respect to the grooves. In addition, particularly, as clarified from FIGS. 7A and 7B, shape abnormality (burr) such as rolling-up of the metal film at the end potions of the grooves is not observed. In addition, particularly, as clarified from FIGS. 7A and 7B, the end portions of the grooves and the end portion of the metal film are coincident with each other so as to be formed as straight lines.

According to the example, it was checked that the metal film of the grooves was able to be removed by the ultrasonic process. In addition, according to the example, it was checked that shape abnormality such as burr of the metal film was suppressed.

In addition, in the embodiment, although the case where the semiconductor device is a vertical type MOSFET or a semiconductor memory is described as an example, the semiconductor device is not limited to the vertical type MOSFET or the semiconductor memory.

In addition, in the first embodiment although the case where the forming of the grooves is performed by plasma etching is described as an example, the forming of the grooves may be performed by blade dicing or laser dicing. In addition, in the second embodiment, although the case where the forming of the grooves is performed by blade dicing is described as an example, the forming of the grooves may be performed by plasma etching or laser dicing.

In addition, in the embodiment, the case where the present invention is used for manufacture a MOSFET or a semiconductor memory is described as an example, the present invention may be applied to the manufacture of an insulated gate bipolar transistor (IGBT), a small-signal system device, or a micro electro mechanical system (MEMS).

In addition, in the embodiment, although the case where a semiconductor substrate is used as the substrate is described as an example, the present invention may be applied to substrates other than the semiconductor substrate, for example, other substrates such as a ceramic substrate, a glass substrate, and a sapphire substrate.

In addition, in the embodiment, although the case where a metal film and a resin film are used as a film formed in the second plane side is described as an example, for example, an inorganic insulating film such as a nitride film or an oxide film or other films may be used.

While certain embodiments have been described, these embodiments have been presented by way of example only, and are not intended to limit the scope of the inventions. Indeed, a device manufacturing method described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A device manufacturing method comprising:
forming a film on a second plane side of a substrate having a first plane and the second plane;
forming grooves on the substrate from the first plane side so that the film remains, the grooves being formed by plasma etching, a sequence of an isotropic etching step, a protective film forming step, and an anisotropic etching step is repeated during the plasma etching;
degassing pure water; and
performing an ultrasonic process on the substrate in the pure water to remove the film at positions where the grooves are formed, a frequency of the ultrasonic process being 20 kHz or more and 80 kHz or less, a power of the ultrasonic process being 200 W or more and 1200 W or less.

2. (canceled)

3. The method according to claim 1, wherein, in forming the grooves, the grooves are formed so that the film is exposed at bottoms of the grooves.

4. The method according to claim 1, wherein, after forming the grooves and before removing the film, a supporting film is attached to the first plane side of the substrate.

5. (canceled)

6. The method according to claim 1, wherein the film is a metal film.

7. The method according to claim 1, wherein the film is a resin film.

8. (canceled)

9. The method according to claim 1, wherein the substrate is a silicon substrate.

10. The method according to claim 1, wherein in degassing the pure water, a hollow fiber membrane is used.
